(19) United States
(12) Patent Application Publication
(10) Pub. No.: US 2004/0069211 A1
(43) Pub. Date: Apr. 15, 2004

(54) Method of forming single crystals of ceramic, semiconductive or magnetic material

(76) Inventors: Sabin Boily, Chambly (CA); Pascal Tessier, Montreal (CA); Houshang Alamdari, Sainte-Julie (CA)

Correspondence Address: FOLEY AND LARDNER, SUITE 500, 3000 K STREET NW, WASHINGTON, DC, 20007, US

(21) Appl. No.: 10/467,770

(22) PCT Filed: Feb. 12, 2002
(86) PCT No.: PCT/CA02/00168

(30) Foreign Application Priority Data
Feb. 12, 2001 (CA) 2335260

(51) Int. Cl. C30B 15/00; C30B 21/06; C30B 27/02; C30B 28/10; C30B 30/04

(52) U.S. Cl. 117/30; 117/32; 117/217

(57) ABSTRACT

The invention is concerned with a method of forming a single crystal of a ceramic, semiconductive or magnetic material. The method according to the invention comprises the steps of (a) compacting a nanocrystalline powder comprising particles having an average particle size of 0.05 to 20 μm and each formed of an agglomerate of grains with each grain comprising a nanocrystal of a ceramic, semiconductive or magnetic material; and (b) sintering the compacted powder obtained in step (a) at a temperature sufficient to cause an exaggerated growth of at least one of the grains, thereby obtaining at least one single crystal of aforesaid material. Instead of sintering the compacted powder, it is also possible to contact same with a template crystal of the aforesaid material, and to heat the compacted powder and template crystal in contact with one another so as to cause a sustained directional growth of the template crystal into the compacted powder, thereby obtaining a single crystal having a size larger than the template crystal. By using nanocrystalline powders, the temperature of operation for crystal growth is reduced, the rate of crystal growth increases, and crystals with large size and with very little or no porosity or inclusions can be obtained.

### TECHNICAL FIELD

The present invention pertains to improvements in the field of single crystals. More particularly, the invention relates to an improved method of forming single crystals of a ceramic, semiconductive or magnetic material.

### BACKGROUND ART

Large size single crystals are of great interest in electronic and optical applications. Single crystals are produced using different techniques such as top-seeded solution growth (TSSG), templated grain growth (TGG) and exaggerated grain growth (EGG). Due to difficulties inherent to these fabrication methods, the commercial cost of single crystals is relatively high.

The TSSG technique involves bringing a seed which is a single crystal into contact with a melt of the material having the same composition as the single crystal to be produced. The seed is brought slowly into contact with the surface of the melt, then it is rotated and pulled up. Since the temperature of the seed is lower than that of the melt, the atoms of the melt join the surface of the seed and crystallize on the seed. By turning and pulling the seed, the latter grows and forms a solid droplet. The bottom of this droplet is always in contact with the melt. The problems encountered in TSSG include:

1. High operating temperature: the starting material must melt and this causes serious problems when the melting point is too high.

2. Strict temperature control: crystal growth occurs within a narrow range of temperature. If the temperature is higher than this range, the seed melts and the contact between the seed and the melt is cut. If the temperature is lower than this range, a sudden undesirable growth occurs and it is possible that the solid be full of solution inclusions, voids and polycrystalline material.

3. Strict control of cooling and pulling rates: pulling and cooling rates are very sensitive to the solid droplet diameter. Moreover, during radial expansion, it is possible that solution trapping or incomplete crystalline formation may occur. These malformed facet intersections can be avoided by gradually decreasing the cooling rate; however, this requires strict control of cooling rate and long run duration.

4. Lack of diameter control and the formation of a solution droplet on the bottom of the solid droplet, which may cause cracking.

The TGG technique involves contacting a template crystal and a sintered polycrystalline matrix and then heating the template crystal and polycrystalline matrix in contact with one another to produce a single crystal via sustained directional growth of the template crystal into the polycrystalline matrix. The driving force for boundary migration is provided by the grain boundary free energy of the polycrystalline matrix. The problems encountered in TGG include:

1. Boundary migration rates and, consequently, template growth are relatively slow because the matrix consists of grains with large size (micron size) which reduces considerably the driving force for template growth.

2. Low driving force and long diffusion paths contribute to increase the temperature necessary for TGG. In general, grain growth occurs within the polycrystalline matrix itself during TGG and reduces the template growth rate considerably.

The EGG technique involves essentially the sintering of a polycrystalline powder at a temperature sufficient to cause some grains to grow abnormally to much large size than the average due an enhanced material transfer in some directions and on some specific planes. Admixing additives can help the exaggerated grain growth. For example, addition of a small amount of SiO₂ or TiO₂ enhances the exaggerated grain growth of BaTiO₃. It has also been reported that placing several seeds (single crystals with a size larger than the powder particle size) in the powder before sintering enhances the exaggerated growth of the seeds. The problems encountered in EGG include:

1. There is no shape control of the final crystal.

2. Since the starting powder contains large particles (micron size), the diffusion rate is slow and this reduces considerably the driving force for crystal growth. Consequently, the rate of crystal growth is too small.

3. A small amount of porosity is present in the grains due to pore trapping within the crystal. Elimination of these pores is very difficult (sometimes impossible) because of the long diffusion paths.

4. The maximum size of single crystal produced by this method is relatively small. The growth rate is high in the early stages of sintering, but it reduces very rapidly by a further increase in particle size.

### DISCLOSURE OF INVENTION

It is therefore an object of the invention to overcome the above drawbacks and to provide an improved method of forming single crystals of a ceramic, semiconductive or magnetic material.

According to one aspect of the invention, there is provided a method of forming a single crystal of a ceramic, semiconductive or magnetic material, in accordance with the EGG technique. Such a method comprises the steps of:

a) compacting a nanocrystalline powder comprising particles having an average particle size of 0.05 to 20 μm and each formed of an agglomerate of grains with each grain comprising a nanocrystal of a ceramic, semiconductive or magnetic material; and

b) sintering the compacted powder obtained in step (a) at a temperature sufficient to cause an exaggerated growth of at least one of the grains, thereby obtaining at least one single crystal of the aforesaid material.

According to another aspect of the invention, there is provided a method of forming a single crystal of a ceramic, semiconductive or magnetic material, in accordance with the TGG technique. Such a method comprises the steps of:

a) compacting a nanocrystalline powder comprising particles having an average particle size of 0.05 to 20 μm and each formed of an agglomerate of grains with each grain comprising a nanocrystal of a ceramic, semiconductive or magnetic material;

b) contacting the compacted powder obtained in step (a) with a template crystal of the aforesaid material; and

c) heating the compacted powder and template crystal in contact with one another to cause a sustained directional growth of the template crystal into the compacted powder, thereby obtaining a single crystal having a size larger than the template crystal.

The term “nanocrystal” as used herein refers to a crystal having a size of 100 nanometers or less.

Nanocrystalline powders exhibit good sinterability. They can be prepared by different techniques such as those described for example in U.S. Pat. Nos. 5,514,349 and 5,958,348. They can also be prepared by a technique called “high-energy ball milling”, as described in Applicant's Canadian Patent Application No. 2,331,470 filed on Jan. 19, 2001 and corresponding to International Application No. PCT/CA02/00070. Depending on the type of the material and the technique of production, the particle size of nanocrystalline powders may lie in the range of 0.05 to 20 μm. When the particles are nanometric in size, the specific area of the powder in this case is very high (20-400 m²/g). However, when the particles are larger, they contain several nanosized crystallites. In such a case, although the specific area of powder is not very high, the material consists of very large quantity of grain boundaries.

Having a large surface area or large quantity of grain boundaries enhances the diffusion rate. In addition, high quantity of grain boundaries, with higher free energy, compared to the grain itself, increases the driving force for densification and grain growth during sintering.

Another factor influencing the driving force for densification and grain growth is the surface energy. Small nanosized grains having a small curvature radius are unstable at high temperatures and possess high chemical potentials. So they have a tendency to join on the flat surfaces or those with large curvature radii in order to minimize the overall free energy.

For all the above reasons, the crystal growth from nanocrystalline powders is rapid and takes place at lower temperatures. By using nanocrystalline powders, the temperature of operation for crystal growth is reduced, the rate of crystal growth increases, and crystals with large size and with very little or no porosity or inclusions can be obtained.

### MODES FOR CARRYING OUT THE INVENTION

Examples of ceramic materials from which single crystals may be formed include aluminum oxide, aluminum nitride and silicon nitride. On the other hand, examples of semiconductive material include zinc oxide and compounds having the formula BaₓTi_{y}O_{z} wherein x and y each range from 0.1 to 20 and z ranges from 0.3 to 60, such as BaTiO₂ and Ba₃Ti₄O₁₁. Where the semiconductive material is a compound of the formula BaₓTi_{y}O_{z}, the nanocrystalline powder of such a material can be obtained by subjecting barium oxide and titanium dioxide to high-energy ball milling to cause solid state reaction therebetween and formation of particles having an average particle of 0.05 to 20 μm, each particle being formed of an agglomerate of grains with each grain comprising a nanocrystal of a compound of the formula BaₓTi_{y}O_{z}. In the particular case of barium titanate (BaTiO₃), the nanocrystalline powder can be obtained by subjecting a barium titanate powder having an average grain size larger than 1 μm to high-energy ball milling to cause formation of particles having an average particle size of 0.05 to 20 μm, each particle being formed of an agglomerate of grains with each grain comprising a nanocrystal of barium titanate.

Examples of magnetic materials include compounds having the formula Sm₂FeₓCo₁₇₋ₓN_{y} wherein 0≦x≦17 and 0≦y≦3, such as Sm₂Fe₁₇, Sm₂Fe₁₇N₃, Sm₂Co₁₇ and Sm₂Co₁₇N₃. It is also possible to use a compound of the formula Nd₂FeₓB_{y} wherein 9<x<19 and 0.3<y<3, such as Nd₂Fe₁₄B.

The expression “high-energy ball milling” as used herein refers to a ball milling process capable of forming the aforesaid particles comprising nanocrystalline grains of the ceramic, semiconductive or magnetic material, within a period of time of about 40 hours.

Where the EGG technique is followed, a grain growth enhancing agent or a seed crystal of the ceramic, semiconductive or magnetic material is preferably added to the nanocrystalline powder, prior to step (a). For example, silica or titanium dioxide can be added in an amount of 0.01 to 8 wt. % to enhance the exaggerated grain growth of BaTiO₃. Step (b), on the other hand, is preferably carried out at a temperature ranging from 0.5 Tₘ to 0.95 Tₘ, where Tₘ is the melting point of the ceramic, semiconductive or magnetic material.

The method of the invention also allows producing very homogeneously doped single crystals. Sometimes, single crystals are doped with elements, ions or compounds in order to modify the optical and electrical properties. In some cases, the doping elements may have a concentration gradient within the single crystal. The use of nanocrystalline powders allows one to prepare very homogeneous powder where the doping elements are distributed in nanometer scale. Growing a single crystal from such a homogenous powder results in a crystal having a very high homogeneous concentration of doping element.

The following non-limiting examples illustrate the invention.

### EXAMPLE 1

A coarse-grained BaTiO₃ powder (99.9% pure) having an average grain size larger than 1 μm was used as starting material. 10 g of this BaTiO₃ powder were milled in a steel crucible using a SPEX 8000 (trademark) vibratory ball mill operated at 16 Hz. After 10 hours of high-energy ball milling, a nanocrystalline BaTiO₃ powder having a particle size between 1 and 5 μm and a mean crystallite size smaller than 100 nm was obtained. The nanocrystalline powder was then pressed uniaxially at a pressure of 250 MPa using a cylindrical die having 1 cm in diameter. The compacted powder thus obtained was sintered at a temperature of 1300° C. for a period of 6 hours. A heating rate of 5° C./min. was used. A polycrystalline bulk material was obtained. A few grains grew to a large size (several millimeters).

### EXAMPLE 2

A coarse-grained BaTiO₃ powder (99.9% pure) having an average grain size larger than 1 μm was used as starting material. 3.96 g of this BaTiO₃ powder and 0.04 g of stearic acid were milled in a silicon nitride crucible using a SPEX 8000 (trademark) vibratory ball mill operated at 16 Hz. After 10 hours of high-energy ball milling, a nanocrystalline BaTiO₃ powder having a mean crystallite size smaller than 100 nm was obtained. The nanocrystalline powder was then uniaxially pressed at a pressure of 250 MPa using a cylindrical die having 1 cm in diameter. The compacted powder thus obtained was sintered at a temperature of 1130° C. for a period of 10 hours. A heating rate of 5° C./min was used. A polycrystalline bulk material was obtained. A few grains grew to a large size (several millimeters).

### EXAMPLE 3

A BaTiO₃ single crystal was prepared according to the same procedure as described in Example 1 or 2 and under the same operating conditions, with the exception that 0.02 g of silica were admixed with the coarse-grained powder, prior to compaction.

### EXAMPLE 4

A BaTiO₃ single crystal was prepared according to the same procedure as described in Example 1 or 2 and under the same operating conditions, with the exception that a seed crystal of BaTiO₃ having a mean diameter of about 1 μm was placed in the coarse-grained powder, prior to compaction.

### EXAMPLE 5

A BaTiO₃ single crystal was prepared according to the same procedure as described in Example 1 or 2 and under the same operating conditions, with the exception that prior to compaction, 0.02 g of titanium dioxide were admixed with the coarse-grained powder and a seed crystal of BaTiO₃ having a mean diameter of about 1 μm was then placed in the powder.

### EXAMPLE 6

A nanocrystalline BaTiO₃ powder was produced by ball milling 7.26 g of BaO and 2.397 g of TiO₂ in a steel crucible using a SPEX 8000 vibratory ball mill operated 16 Hz. After 10 hours of high-energy ball milling, a nanocrystalline powder consisting of BaTiO₃ and having a particle size varying between 1 and 5 μm was obtained. The crystallite size, measured by X-ray diffraction, was about 20 nm. The nanocrystalline powder was then pressed uniaxially at a pressure of 250 MPa using a cylindrical die having 1 cm in diameter. The compacted powder thus obtained was sintered at a temperature of 1300° C. for a period of 6 hours. A heating rate of 5° C./min. was used. A polycrystalline bulk material was obtained. A few grains grew to a large size (several millimeters).

### EXAMPLE 7

A nanocrystalline Ba₃Ti₄O₁₁ powder was produced by ball milling 7.26 g of BaO and 3.196 g of TiO₂ in a steel crucible using a SPEX 8000 vibratory ball mill operated 16 Hz. After 10 hours of high-energy ball milling, a nanocrystalline powder consisting of Ba₃Ti₄O₁₁ and having a particle size varying between 1 and 5 μm was obtained. The crystallite size, measured by X-ray diffraction, was about 20 nm. The nanocrystalline powder was then pressed uniaxially at a pressure of 250 MPa using a cylindrical die having 1 cm in diameter. The compacted powder thus obtained was sintered at a temperature of 1300° C. for a period of 6 hours. A heating rate of 5° C./min. was used. A polycrystalline bulk material was obtained. A few grains grew to a large size (several millimeters).

### EXAMPLE 8

A thin film of BaTiO₃ was deposited on a MgO substrate by chemical deposition to form a template crystal of BaTiO₃. A nanocrystalline BaTiO₃ powder produced by high-energy ball milling as described in Example 1 or 6 was pressed uniaxially at a pressure of 250 MPa using a cylindrical die having 1 cm in diameter. The compacted powder thus obtained was placed on the BaTiO₃ thin film and the combination was heated at a temperature of 1200° C. to cause a sustained directional growth of the template crystal in the compacted powder. A single crystal of BaTiO₃ having a size larger than the template crystal was obtained.

### EXAMPLE 9

The surface of a BaTiO₃ single crystal prepared in accordance with any one of Examples 1 to 6 were polished. The single crystal was placed at the center of a die and the void in the die around the crystal was filled with nanocrystalline BaTiO₃ powder containing a dopant element in a predetermined concentration. The powder was then pressed isostatically at a pressure of 250 MPa. The compacted powder was sintered at 1300° C. for a period of 6 hours. These steps were repeated with different concentrations of dopant element in order to obtain several layers of dopant having a concentration gradient around the single crystal.

### EXAMPLE 10

A thin film of BaTiO₃ was deposited on a MgO substrate by chemical deposition to form a template crystal of BaTiO₃. A nanocrystalline powder produced by high-energy ball milling as described in Example 2 was pressed axially at a pressure of 250 MPa using a cylindrical die having 1 cm in diameter. The compacted powder thus obtained was placed on the BaTiO₃ thin film and the combination was heated at a temperature of 1130° C. to cause a sustained directional growth of the template crystal in the compacted powder. A single crystal of BaTiO₃ having a size larger than the template crystal was obtained.

1. A method of forming a single crystal of a ceramic, semiconductive or magnetic material, comprising the steps of:
a) compacting a nanocrystalline powder comprising particles having an average particle size of 0.05 to 20 μm and each formed of an agglomerate of grains with each grain comprising a nanocrystal of a ceramic, semiconductive or magnetic material; and
b) sintering the compacted powder obtained in step (a) at a temperature sufficient to cause an exaggerated growth of at least one of said grains, thereby obtaining at least one single crystal of said material.

2. A method according to claim 1, wherein prior to step (a), a grain growth enhancing agent is added to said nanocrystalline powder.

3. A method according to claim 1, wherein prior to step (a), a seed crystal of said material is added to said nanocrystalline powder.

4. A method according to claim 1, wherein said ceramic, semiconductive or magnetic material has a melting point and wherein step (b) is carried out at a temperature ranging from 0.5 Tₘ to 0.95 Tₘ, where Tₘ is the melting point of said material.

5. A method according to claim 1, wherein each said grain comprises a nanocrystal of a ceramic material.

6. A method as claimed in claim 5, wherein said ceramic material is selected from the group consisting of aluminum oxide, aluminum nitride and silicon nitride.

7. A method according to claim 1, wherein each said grain comprises a nanocrystal of a semiconductive material.

8. A method according to claim 7, wherein said semiconductive material is barium titanate or zinc oxide.

9. A method according to claim 7, wherein said semiconductive material is barium titanate and wherein, prior to step (a), a grain growth enhancing agent is added to said nanocrystalline powder.

10. A method according to claim 9, wherein said grain growth enhancing agent comprises silica or titanium dioxide.

11. A method according to claim 7, wherein said semiconductive material is barium titanate and wherein said nanocrystalline powder is obtained by subjecting a barium titanate powder having an average grain size larger than 1 μm to high-energy ball milling to cause formation of particles having an average particle size of 0.05 to 20 μm, each particle being formed of an agglomerate of grains with each grain comprising a nanocrystal of barium titanate.

12. A method according to claim 7, wherein said semiconductive material is a compound of formula BaₓTi_{y}O_{z} in which x and y each range from 0.1 to 20 and z ranges from 0.3 to 60, and wherein said nanocrystalline powder is obtained by subjecting barium oxide and titanium dioxide to high-energy ball milling to cause solid state reaction therebetween and formation of particles having an average particle of 0.05 to 20 μm, each particle being formed of an agglomerate of grains with each grain comprising a nanocrystal of a compound of the formula BaₓTi_{y}O_{z}.

13. A method according to claim 12, wherein said semiconductive material is Ba₃Ti₄O₁₁.

14. A method according to claim 1, wherein each said grain comprises a nanocrystal of a magnetic material.

15. A method according to claim 14, wherein said magnetic material is a compound of the formula:
Sm₂FeₓCo₁₇₋ₓN_{y}
wherein0≦x≦17 and 0≦y≦3.

16. A method according to claim 15, wherein said magnetic material is a compound selected from the group consisting of Sm₂Fe₁₇, Sm₂Fe₁₇N₃, Sm₂Co₁₇ and Sm₂Co₁₇N₃.

17. A method according to claim 14, wherein said magnetic material is a compound of the formula:
Nd₂FeₓB_{y}
wherein 9<x<19 and 0.3<y<3.

18. A method according to claim 17, wherein said magnetic material is Nd₂Fe₁₄B.

19. A method according to claim 1, wherein said nanocrystalline powder has an average particle size ranging from 1 to 5 μm.

20. A method of forming a single crystal of a ceramic, semiconductive or magnetic material, comprising the steps of:
a) compacting a nanocrystalline powder comprising particles having an average particle size of 0.05 to 20 μm and each formed of an agglomerate of grains with each grain comprising a nanocrystal of a ceramic, semiconductive or magnetic material; and
b) contacting the compacted powder obtained in step (a) with a template crystal of said material; and
c) heating the compacted powder and template crystal in contact with one another to cause a sustained directional growth of the template crystal into the compacted powder, thereby obtaining a single crystal having a size larger than said template crystal.

21. A method according to claim 20, wherein each said grain comprises a nanocrystal of a ceramic material.

22. A method as claimed in claim 21, wherein said ceramic material is selected from the group consisting of aluminum oxide, aluminum nitride and silicon nitride.

23. A method according to claim 20, wherein each said grain comprises a nanocrystal of a semiconductive material.

24. A method according to claim 23, wherein said semiconductive material is barium titanate or zinc oxide.

25. A method according to claim 23, wherein said semiconductive material is barium titanate and wherein said nanocrystalline powder is obtained by subjecting a barium titanate powder having an average grain size larger than 1 μm to high-energy ball milling to cause formation of particles having an average particle size of 0.05 to 20 μm, each particle being formed of an agglomerate of grains with each grain comprising a nanocrystal of barium titanate.

26. A method according to claim 23, wherein said semiconductive material is a compound of formula BaₓTi_{y}O_{z} in which x and y each range from 0.1 to 20 and z ranges from 0.3 to 60, and wherein said nanocrystalline powder is obtained by subjecting barium oxide and titanium dioxide to high-energy ball milling to cause solid state reaction therebetween and formation of particles having an average particle of 0.05 to 20 μm, each particle being formed of an agglomerate of grains with each grain comprising a nanocrystal of a compound of the formula BaₓTi_{y}O_{z}.

27. A method according to claim 26, wherein said semiconductive material is Ba₃Ti₄O₁₁.

28. A method according to claim 20, wherein each said grain comprises a nanocrystal of a magnetic material.

29. A method according to claim 28, wherein said magnetic material is a compound of the formula:
Sm₂FeₓCo₁₇₋ₓN_{y}
wherein 0≦x≦17 and 0≦y≦3.

30. A method according to claim 29, wherein said magnetic material is a compound selected from the group consisting of Sm₂Fe₁₇, Sm₂Fe₁₇N₃, Sm₂Co₁₇ and Sm₂Co₁₇N₃.

31. A method according to claim 28, wherein said magnetic material is a compound of the formula:
Nd₂FeₓB_{y}
wherein 9<x<19 and 0.3<y<3.

32. A method according to claim 31, wherein said magnetic material is Nd₂Fe₁₄B.

33. A method according to claim 20, wherein said nanocrystalline powder has an average particle size ranging from 1 to 5 μm.
